(19) United States
(12) Patent Application Publication
(10) Pub. No.: US 2026/0332126 A1
(43) Pub. Date: Oct. 22, 2026

(54) SOLIDLY-MOUNTED ACOUSTIC RESONATORS WITH A REDUCED AREA OF A PIEZOELECTRIC LAYER

(71) Applicant: Murata Manufacturing Co., Ltd., Nagaokakyo-shi (JP)

(72) Inventors: Bryant GARCIA, Mississauga (CA); Patrick TURNER, Portola Valley, CA (US)

(21) Appl. No.: 19/639,052

(22) Filed: Apr. 3, 2026

Related U.S. Application Data
(60) Provisional application No. 63/791,012, filed on Apr. 18, 2025.

(51) Int. Cl. H03H 9/17; H03H 9/02; H03H 9/56

(52) U.S. Cl. CPC H03H 9/175; H03H 9/02015; H03H 9/02228; H03H 9/568

(57) ABSTRACT

An acoustic resonator includes a piezoelectric layer, a Bragg stack between a substrate of the acoustic resonator and the piezoelectric layer, and an interdigital transducer (IDT) at a surface of the piezoelectric layer that faces away from the Bragg stack. The IDT includes a plurality of fingers including first and second plurality of fingers interleaved and extending along a first axis. The first and second plurality of fingers overlap for a distance O along the first axis. A distance L along a second axis perpendicular to the first axis is between outermost fingers of the plurality of fingers. A size AP of the piezoelectric layer along the first axis is substantially (O + N×p). A size Lp of the piezoelectric layer along the second axis is substantially (L + M×p). N is between -1 and 1. M is between 0 and 1. p is a pitch along the second axis.

### CROSS REFERENCE TO RELATED APPLICATIONS

This application claims priority to U.S. Patent Provisional Application No. 63/791,012, filed Apr. 18, 2025, the entire contents of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

### SUMMARY

As noted above, resonator performance improvements, such as an improved Q factor, also have an improvement effect on the RF filters and network devices that include the improved resonator. As further described herein, a trench in the piezoelectric layer located near or at the interdigital transducer (IDT)-busbar area (BE Gap) is used in a resonator structure to improve Q factor of the resonator. Structures in the BE Gap generally affect acoustic leakage and mode suppression and a trench or a trench structure described herein achieves an improved Q factor by reducing acoustic leakage in the BE Gap. Additionally, fabrication of the described trench and improvement of the Q factor as described herein may be achieved without etching through the metal layer of the IDT. Accordingly, Q factor of resonator devices may be improved by using the described trench without affecting the metal layer of the IDT.

In an exemplary aspect, an acoustic resonator is provided that includes a piezoelectric layer; a Bragg stack disposed between a substrate of the acoustic resonator and the piezoelectric layer; and an interdigital transducer (IDT) at a surface of the piezoelectric layer that faces away from the Bragg stack. The IDT includes a plurality of fingers including a first plurality of fingers and a second plurality of fingers that are interleaved and extend in a direction substantially along a first axis. The first and second plurality of fingers overlap for a distance O along the first axis. A center-to-center distance L along a second axis substantially perpendicular to the first axis is between outermost fingers of the plurality of fingers of the IDT. A pitch p is a center-to-center spacing along the second axis between adjacent fingers of the plurality of fingers, a size AP of the piezoelectric layer along the first axis is substantially equal to (O + N×p), N is a value, such as an integer or a non-integer, between -1 and 1, and a size Lp of the piezoelectric layer along the second axis is substantially equal to (L + M×p), and M is a value between 0 and 1.

In another exemplary aspect, a filter device is provided that includes a plurality of bulk acoustic resonators each including an acoustic resonator is provided that includes a piezoelectric layer; a Bragg stack disposed between a substrate and the piezoelectric layer; and an interdigital transducer (IDT) at a surface of the piezoelectric layer that faces away from the Bragg stack. The IDT includes a plurality of fingers including a first plurality of fingers and a second plurality of fingers that are interleaved and extend in a direction substantially along a first axis. The first and second plurality of fingers overlap for a distance O along the first axis. A center-to-center distance L along a second axis substantially perpendicular to the first axis is between outermost fingers of the plurality of fingers of the IDT. A pitch p is a center-to-center spacing along the second axis between adjacent fingers of the plurality of fingers, a size AP of the piezoelectric layer along the first axis is substantially equal to (O + N×p), N is a value between -1 and 1, and a size Lp of the piezoelectric layer along the second axis is substantially equal to (L + M×p), and M is a value between -0 and 1.

In another exemplary aspect, a radio frequency module is provided that includes a filter device including a plurality of bulk acoustic resonators; and a radio frequency circuit coupled to the filter device, the filter device and the radio frequency circuit being enclosed within a common package. In this aspect, at least one of the plurality of bulk acoustic resonators of the filter device includes a piezoelectric layer; a Bragg stack disposed between a substrate and the piezoelectric layer; and an interdigital transducer (IDT) at a surface of the piezoelectric layer that faces away from the Bragg stack. The IDT includes a plurality of fingers including a first plurality of fingers and a second plurality of fingers that are interleaved and extend in a direction substantially along a first axis. The first and second plurality of fingers overlap for a distance O along the first axis. A center-to-center distance L along a second axis substantially perpendicular to the first axis is between outermost fingers of the plurality of fingers of the IDT. A pitch p is a center-to-center spacing along the second axis between adjacent fingers of the plurality of fingers, a size AP of the piezoelectric layer along the first axis is substantially equal to (O + N×p), N is a value between -1 and 1, and a size Lp of the piezoelectric layer along the second axis is substantially equal to (L + M×p), and M is a value between -0 and 1.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIGS. 1A and 1B include a schematic plan view and a schematic cross-sectional view of a transversely-excited film bulk acoustic resonator (XBAR).

FIG. 2A is an expanded schematic cross-sectional view of a portion of the XBAR of FIGS. 1A and 1B.

FIG. 2B is an expanded schematic cross-sectional view of an alternative configuration of the XBAR of FIGS. 1A and 1B.

FIG. 2C is an expanded schematic cross-sectional view of another alternative configuration of the XBAR of FIGS. 1A and 1B.

FIG. 2D is an expanded schematic cross-sectional view of another alternative configuration of the XBAR of FIGS. 1A and 1B.

FIG. 3 is an expanded schematic cross-sectional view of a portion of a solidly-mounted XBAR (SM XBAR).

FIG. 4 is a graphic illustrating a shear horizontal acoustic mode in an XBAR.

FIG. 5A is a schematic block diagram of a filter using XBAR of FIGS. 1A and 1B.

FIG. 5B is a schematic diagram of a radio frequency module that includes an acoustic wave filter device according to an exemplary aspect.

FIGS. 6A-6B show a planar view and a cross-sectional view of an SM XBAR having a reduced area of a piezoelectric layer according to an exemplary aspect.

FIG. 7A is a planar view of an SM XBAR having a reduced area of a piezoelectric layer and having a trench according to an exemplary aspect.

FIGS. 7B and 7C show cross-sectional views illustrating the trench of FIG. 7A according to an exemplary aspect.

FIG. 7D shows cross-sectional view illustrating the trench of FIG. 7A according to another exemplary aspect.

FIG. 8 is a planar view of an SM XBAR having a trench between adjacent fingers according to an exemplary aspect.

FIG. 9A is a planar view of an SM XBAR having trenches extending along a first axis and a second axis, respectively, according to an exemplary aspect.

FIG. 9B is a planar view of an SM XBAR having a connected trench according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

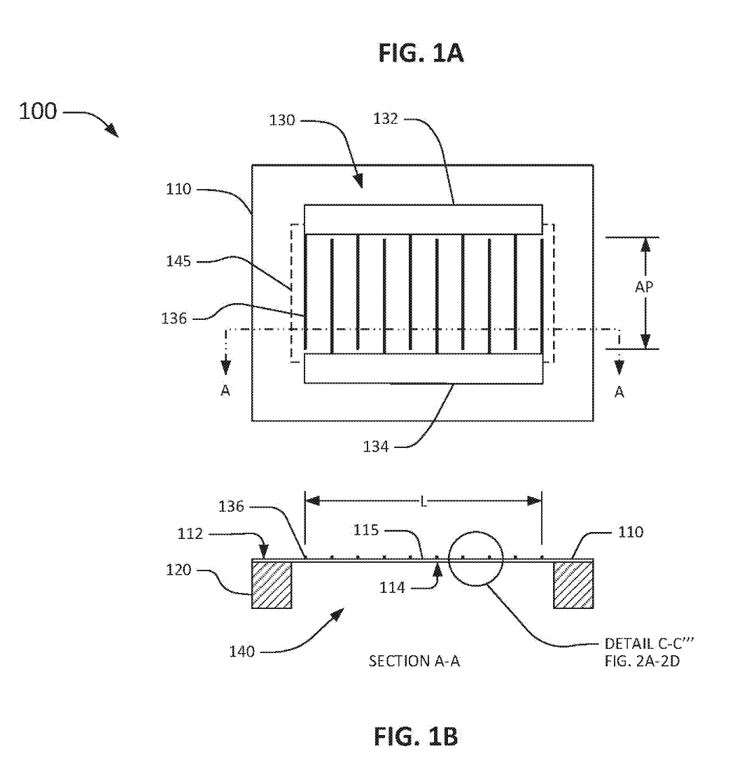

FIGS. 1A and 1B illustrate simplified schematic top view and orthogonal cross-sectional views, respectively, of an acoustic resonator device, namely a transversely excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” The piezoelectric layer may be, for example, a rotated Y-cut lithium niobate or a rotated Y-cut lithium tantalate, and the cut angle may be 80° to 100° or 110° to 130°. Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer, an aluminum oxide or a silicon nitride), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1B, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, aluminum nitride, spinel, lithium tantalate, lithium niobate, magnesia, silicon nitride, aluminum oxide, silicon carbide, zirconia, cordierite, mullite, steatite, forsterite, diamond, glass, gallium nitride or some other material or combination of materials. In the case where the substrate 120 is silicon, the plane orientation of the surface coupled or connected either directly or indirectly, via one or more intermediate layers, to the back side 114 of the piezoelectric layer 110 may be, for example, a (100) plane, (110) plane, or (111) plane, and the resistivity may be more than or equal to 4 kΩ. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer, or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. For example, the distance AP may be 30 micrometers (µm). The center-to-center distance L between the outermost fingers of the IDT 130 is the “length” of the IDT. In another exemplary aspect, the IDT 130 may include only one first finger extending from the first busbar 132 and only one second finger extending from the second busbar 136.

In the example of FIGS. 1A and 1B, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

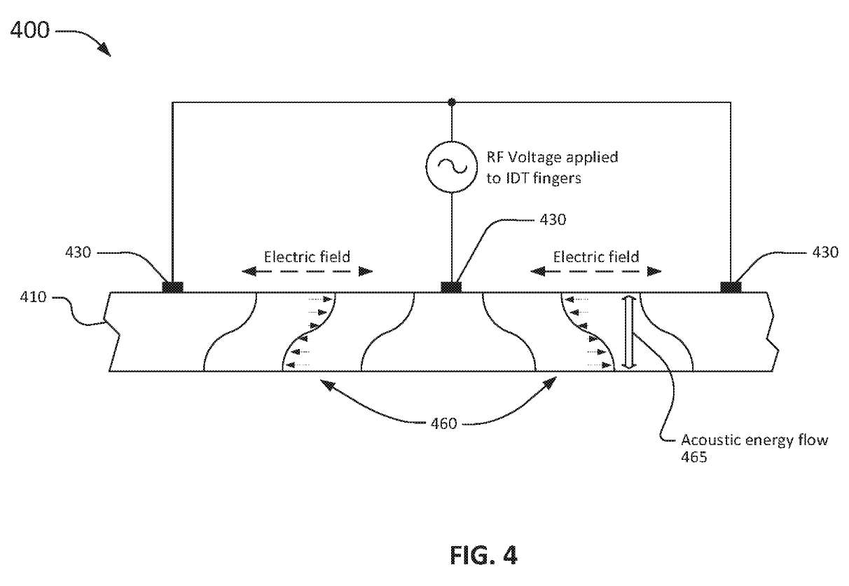

The first and second busbars 132, 134 are configured as the terminals of the XBAR 100 with the plurality of interleaved fingers extending therefrom. The busbars such as 132, 134 may be made of the same or different materials as the fingers. The thickness of the busbars may be the same as, less than, or greater than the thickness tm of the IDT fingers. In an example, the busbars are positioned in an area different from wire line routing and are different in shape than wire line routing. In an example, the busbars have unique electrical characteristics. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely-excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1B, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved. According to the exemplary aspect, an angle between a direction substantially parallel to the length L of the IDT and the X crystalline axis may be 0° to 30°.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in µm². Thus, the area of the XBAR 100 may be adjusted based on design choices, thereby adjusting the overall capacitance of the XBAR 100.

For ease of presentation in FIGS. 1A and 1B, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

In an exemplary aspect, openings (not shown) may be provided in the diaphragm 115. The openings are through holes penetrating the piezoelectric layer 110. The openings may have a rectangular shape in the plan view and be provided along edges of the openings extending in a direction that the plurality of interleaved fingers extend. A portion of the one or more intermediate layers or the substrate and a portion of the cavity 140 may be provided in regions overlapping each of the openings. Any suitable shape, number and/or position of the openings may be adjusted based on design choices.

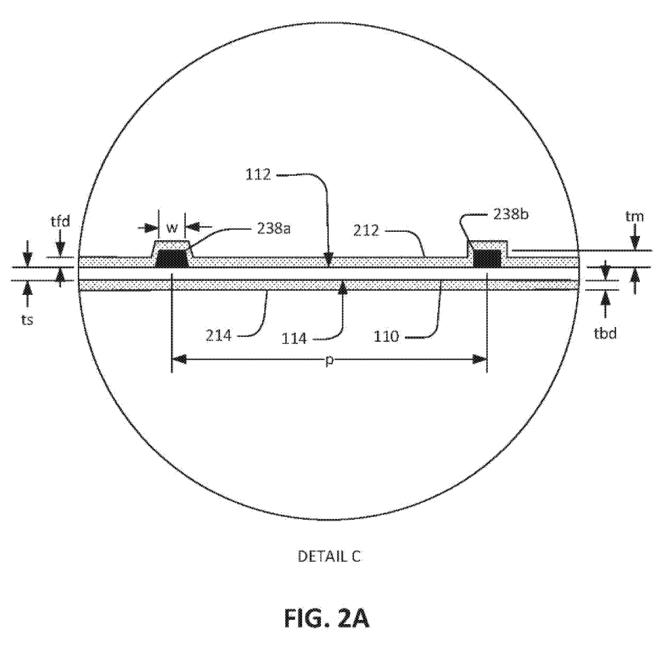

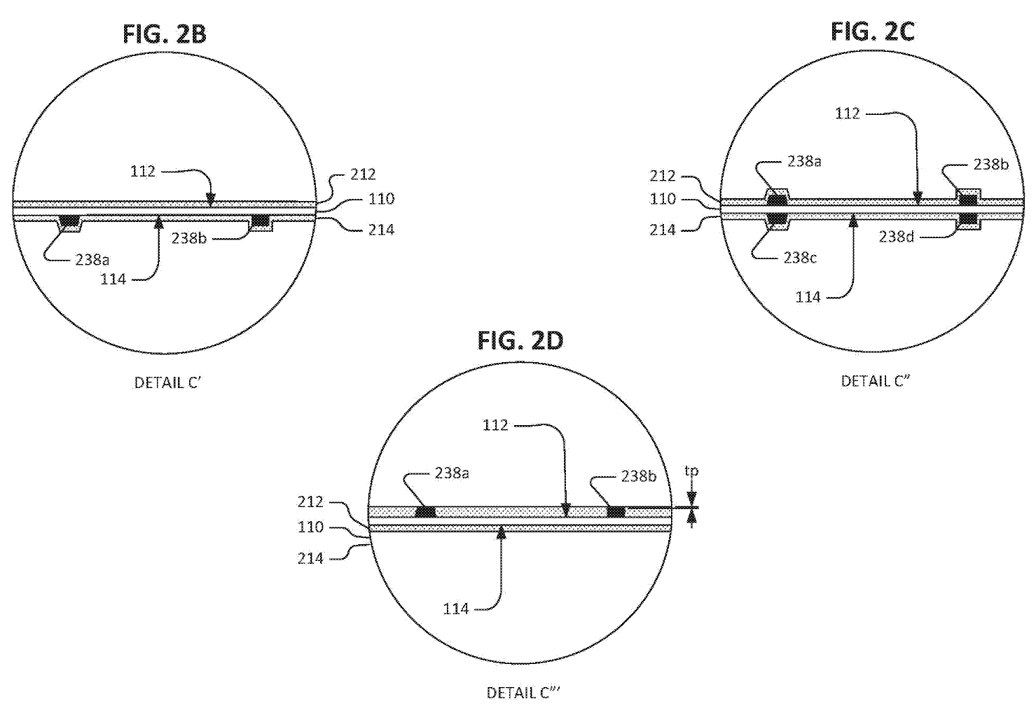

FIG. 2A shows a detailed schematic cross-sectional view of the XBAR 100 of FIGS. 1A and 1B. The piezoelectric layer 110 is a single-crystal layer of piezoelectrical material having a thickness ts. ts may be, for example, 100 nanometers (nm) to 1500 nm. When used in filters for 5G NR and Wi-Fi^{TM} bands from 3.4 GHZ to 7 GHz, the thickness ts may be, for example, 150 nm to 500 nm. The thickness ts can be measured in a direction substantially perpendicular or orthogonal to a surface of the piezoelectric layer in an exemplary aspect. In the case that the thickness of the piezoelectric layer 110 has variances, the thickness ts may be the average value.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIGS. 1A and 1B. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide, silicon nitride, aluminum nitride, aluminum oxide, tantalum oxide, niobium oxide and the like. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially aluminum alloys, copper, substantially copper alloys, molybdenum, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIGS. 1A and 1B) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. The pitch p may be, for example, 1 microns (µm) to 10 µm. Moreover, center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A-2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIGS. 1A and 1B.

In general, the IDT of an XBAR differs substantially from the IDTs used in surface acoustic wave (SAW) resonators, primarily in that IDTs of an XBAR excite a shear acoustic mode (also referred to as a shear mode, a shear thickness mode, or the like), as described in more detail below with respect to FIG. 4, where SAW resonators excite a surface wave in operation. For example, the wave mode may be a zeroth order mode, a first order mode, a secondary mode, a tertiary mode or higher order modes. In a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIGS. 1A and 1B) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C’) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C’’) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C’’’) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A-2D include a diaphragm spanning over a cavity. However, in an alternative aspect, the acoustic resonator can be solidly mounted in which the diaphragm with IDT fingers is mounted on or above an acoustic mirror, such as a Bragg mirror or Bragg stack, which in turn can be mounted on a substrate.

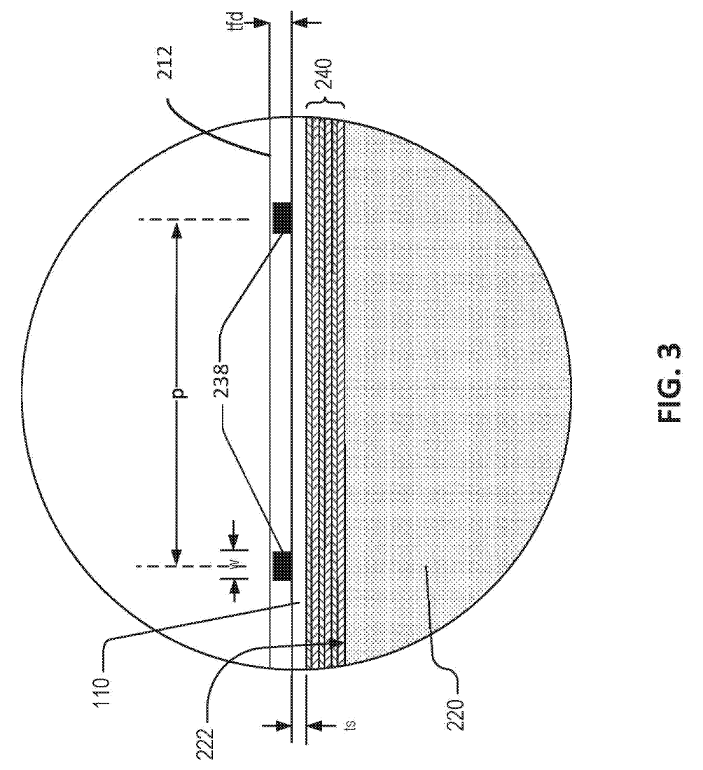

In particular, FIG. 3 shows a detailed schematic cross-sectional view of a solidly mounted XBAR (SM XBAR). The SM XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p. It should be appreciated that the pair of IDT fingers 238 are interleaved fingers of an IDT having a plurality of interleaved fingers as described above.

In contrast to the XBAR devices shown in FIGS. 1A and 1B, the IDT of an SM XBAR in FIG. 3 is not formed on a diaphragm spanning a cavity in the substrate. Instead, an acoustic Bragg reflector 240 (also referred to as a Bragg mirror, Bragg stack, or multilayer acoustic reflector) is sandwiched between a surface 222 of the substrate 220 and the back surface of the piezoelectric layer 110. The term “sandwiched” means the layers of the acoustic Bragg reflector 240 are both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple layers that alternate between materials having high acoustic impedance and materials having low acoustic impedance. The acoustic impedance of a material is the product of the material’s shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide, tungsten carbide, tantalum carbide, rhenium oxide, chromium silicon carbide, niobium carbide, zirconium carbide, zirconium nitride, lanthanum boride, vanadium carbide, yttrium oxide, magnesium oxide, boron carbide, strontium fluoride, barium fluoride, tantalum oxide, tantalum oxide, tungsten oxide, hafnium nitride, tungsten nitride, platinum, tungsten, copper, gold and silver. All of the high acoustic impedance layers of the acoustic Bragg reflector 240 are not necessarily the same material, and all of the low acoustic impedance layers are not necessarily the same material. In the example of FIG. 3, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer. Moreover, in another exemplary aspect as discussed below, the conductor pattern, which includes the IDT, can be disposed between the piezoelectric layer and the Bragg reflector 240.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A-2D and FIG. 3 according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465. Thus, even if the number of pairs of the IDT fingers 430 is reduced to miniaturize the XBAR 400, the Q factor is less likely to be decreased in many cases. Additionally, the XBAR 400 does not require reflectors sandwiching the IDT fingers 430 in the lateral direction.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

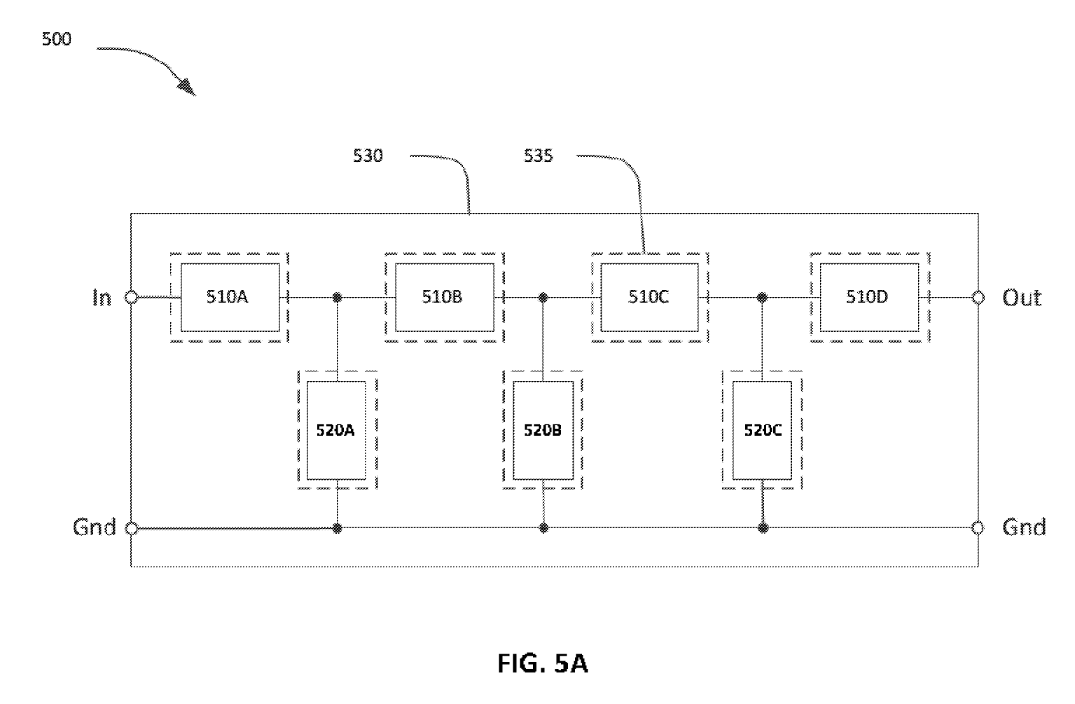

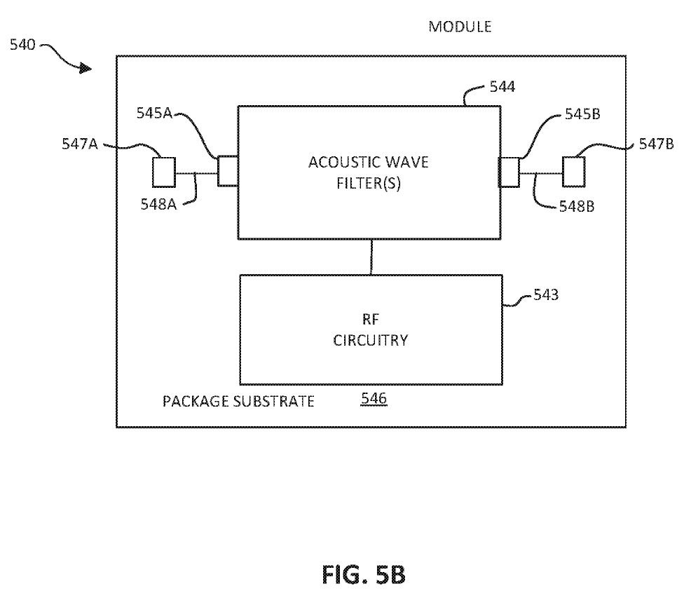

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least three shunt resonators, such as the shunt resonators 520A-520C, are connected from nodes between series resonators to a ground connection. A filter may contain additional reactive components, such as inductors, not shown in FIG. 5A. At least one resonator of the series resonators 510A, 510B, 510C and 510D and the shunt resonators 520A, 520B and 520C may include divided resonators connected in series and/or parallel. Divided resonators may be referred to as “sub-resonators” wherein two or more sub-resonators are resonators having an aperture and length that are substantially similar to each other. This may be done to target the same frequency while reducing the static capacitance of a resonator that would otherwise be larger if not divided into two or more sub-resonators. In some cases, a pitch, or average pitch, of two or more sub-resonators may be same as well, while in some cases slight variations of pitch or average pitch may exist between divided sub-resonators. All the shunt resonators and series resonators are XBARs (e.g., the XBAR configurations 100 as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however, different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter’s passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 3), which in turn can be mounted on a substrate. In this case, the cavities (e.g., identified as rectangles 535) would be omitted. Instead, one or more Bragg mirrors can be disposed one, some or all of the resonators of the ladder filter.

FIG. 5B is a schematic diagram of a radio frequency module that includes an acoustic wave filter device according to an exemplary aspect. In particular, FIG. 5B illustrates a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures, for example, to provide protection and/or facilitate easier handling of the radio frequency module 540. Such a packaging structure can include an overmold structure formed over the package substrate 546. The overmold structure can encapsulate some or all of the components of the radio frequency module 540.

In some examples, a filter loss of an RF filter device includes a transverse radiation loss, which can be a significant portion of the filter loss budget. According to an exemplary aspect, an RF filter device, such as the filter 500 described above with respect to FIG. 5A or the acoustic wave filters 544 described above with respect to FIG. 5B, can be configured to include SM XBARs having a piezoelectric layer with a reduced area in a surface of the piezoelectric layer. In such an RF filter device, portions of the piezoelectric layer that is outside an overlapped region of a plurality of interleaved fingers in an IDT are removed to reduce a transverse radiation loss, and thus to reduce a filter loss of the RF filter device and improving filter performance. For example, the piezoelectric layer is limited or comparable to an overlapped region of a first plurality of fingers and a second plurality of fingers along a length of the IDT fingers.

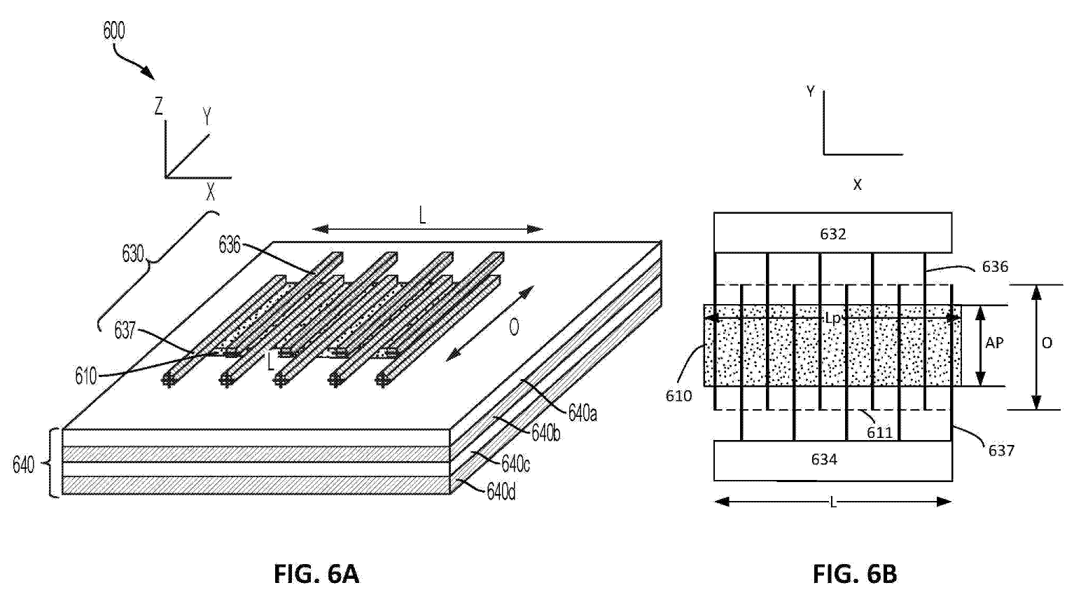

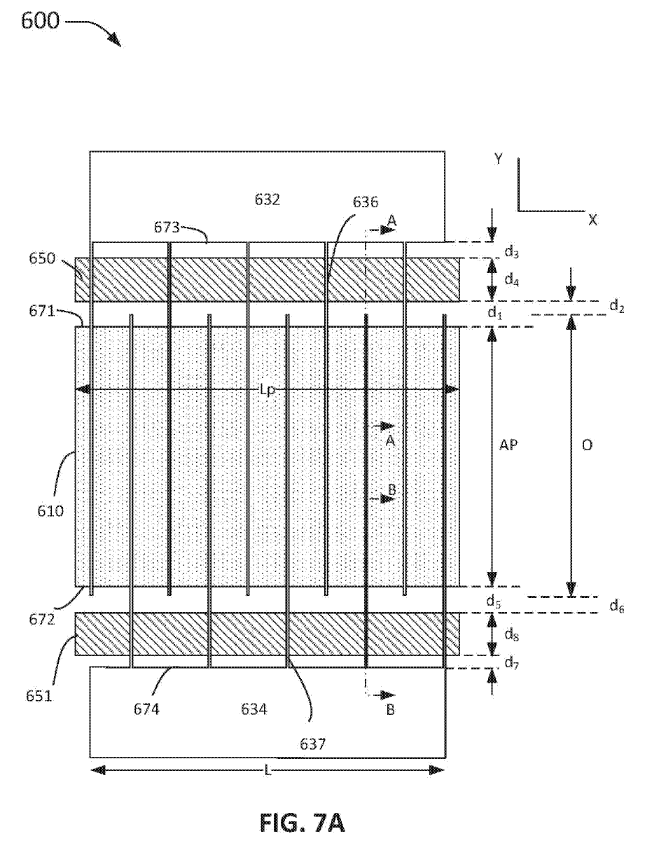

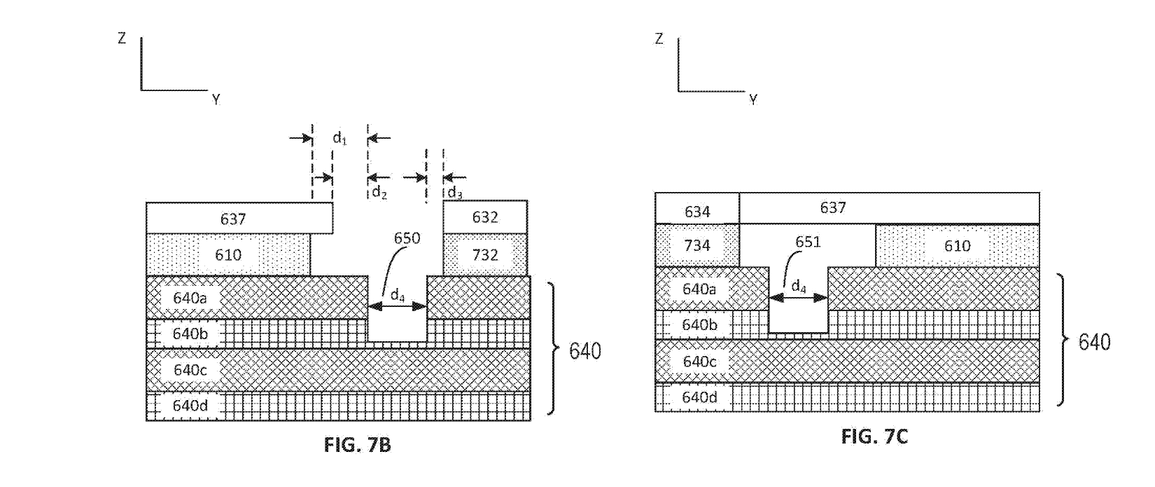

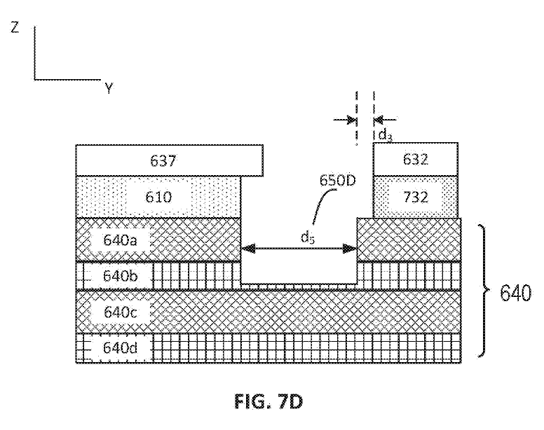

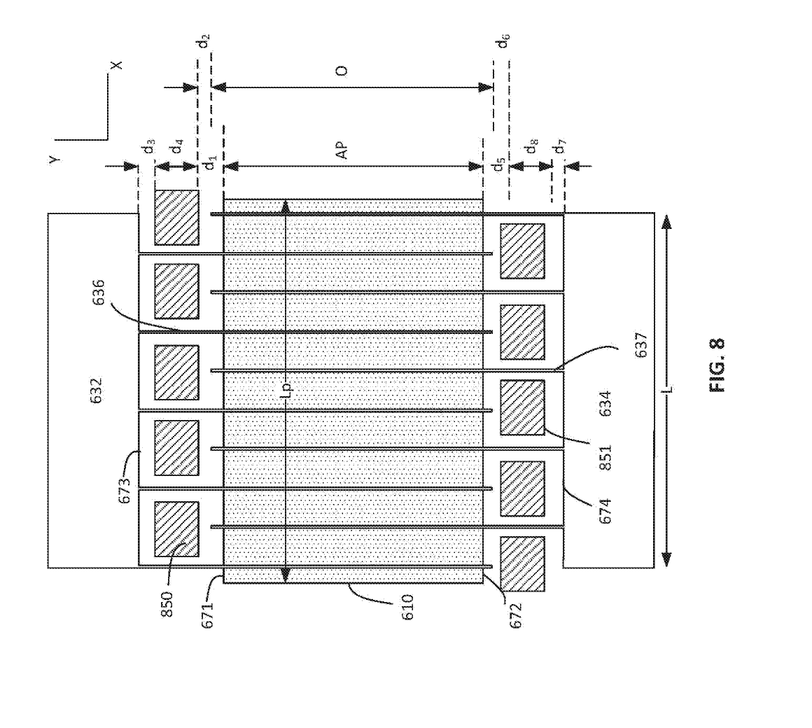

According to an aspect of the disclosure, the SM XBARs having a reduced area (or a limited area) of the piezoelectric layer can be configured to have at least one region where a part of the Bragg stack is removed to improve the Q factor of the SM XBARs by reducing acoustic leakage, thereby improving filter performance. FIGS. 6A-6B show examples of an SM XBAR having a reduced area of the piezoelectric layer. Each of the exemplary embodiments described below with reference to FIGS. 7A-7D, 8, 9A and 9B, illustrates an exemplary embodiment in which at least one trench is disposed between the piezoelectric layer and at least one busbar. As will be described in more detail below, the at least one trench extends partially or completely into the Bragg stack below the conductor pattern to improve the Q factor of the acoustic resonator.

For purposes of the exemplary embodiment described below with reference to FIGS. 6A-6B, 7A-7D, 8, and 9A-9B, each acoustic resonator is shown with respect to X, Y and Z axes. The X-Y plane generally defines a plane that is substantially parallel to a first surface of the piezoelectric layer as described herein. The Z axis extends in the vertical or thickness direction of the acoustic resonators. Moreover, the Y axis is considered a “first direction” for purposes of this disclosure, the X axis is considered a “second direction” for purposes of this disclosure, and the Z axis is considered a “third direction” for purposes of this disclosure. It should be appreciated that for purposes of this disclosure, the term “substantially”, “substantially orthogonal”, “substantially parallel”, “orthogonal”, or “parallel”, takes into account manufacturing variances and that the angles can accounting for a small tolerance, such as +5° or -5°.

FIGS. 6A-6B show a perspective view and a top view of an SM XBAR 600 according to an aspect of the disclosure. The SM XBAR 600 can include a piezoelectric layer 610, a Bragg stack 640 disposed between a substrate (not shown) of the SM XBAR 600 and the piezoelectric layer 610, and an IDT 630. The IDT 630 can be disposed at a first surface of the piezoelectric layer 610 that faces away from the Bragg stack 640. The piezoelectric layer 610 can be disposed between the IDT 630 and the Bragg stack 640. In an example, a second surface of the piezoelectric layer 610 is directly over the Bragg stack 640. In an example, the second surface of the piezoelectric layer 610 is directly over a dielectric layer that is between the Bragg stack 640 and the piezoelectric layer 610. The Bragg stack 640 may include any suitable number of alternating layers as described with reference to FIGS. 3, 6A. shows only four alternating layers 640a, 640b, 640c, and 640d. The Bragg stack 640 may include more or fewer layers (e.g., layers 640a to 640d) in alternative aspects. Moreover, according to an exemplary aspect, an area of the top layer of the Bragg stack 640 in a plan view thereof can be ± 10% of an area of the piezoelectric layer 610 in a plan view in order to provide mechanical stability, for example.

The IDT 630 can include a plurality of interleaved fingers including a first plurality of fingers 636 and a second plurality of fingers 637 that are interleaved with each other. The interleaved fingers 636 and 637 can generally correspond to fingers 136 of FIGS. 1A and 1B and/or fingers 238 of FIG. 3 for the SM-XBAR. In an example, the plurality of interleaved fingers is parallel (e.g., substantially parallel) along the first axis (e.g., the Y axis). In some examples, the first and second busbars 632 and 634 are electrically coupled to first and second metal layers (not shown) that are located between the interleaved fingers 636 and 637 of the IDT and the first and second busbars 632 and 634, respectively, by one or more electrically conductive vias (not shown), for example. In an exemplary aspect, the first metal layer and the first busbar 632 can collectively be considered to form a busbar, such as the busbar 132 of FIGS. 1A and 1B or the first busbar 632. Similarly, in an exemplary aspect, the second metal layer and the second busbar 634 can collectively be considered to form a busbar, such as the busbar 134 of FIGS. 1A and 1B or the second busbar 634.

The first and second plurality of fingers 636 and 637 overlap for a distance O (also referred to an overlapped size) along the first axis. A center-to-center distance L along the second axis (e.g., the X axis) that is substantially perpendicular to the first axis is between outermost fingers of the plurality of interleaved fingers. Thus, an overlapped region 611 within the X-Y surface between the first and second plurality of fingers 636 and 637 has an area of L×O. In an example, the region 611 within the X-Y surface is formed by the overlapping of the first and second plurality of fingers 636 and 637 along the Y axis.

According to an aspect of the disclosure, a portion of the piezoelectric layer 610 that is outside the overlapped region 611 can be removed, and thus an area of the piezoelectric layer 610 is decreased or limited to reduce a loss (e.g., a transverse radiation loss) and improve Q (e.g., a Q factor, also known as Quality Factor or Q-factor, may be defined as a dimensionless parameter that describes the underdamped condition of an oscillator or resonator) and measures the performance in terms of its losses and resonator bandwidth measure of the SM XBAR 600. A size AP of the piezoelectric layer 610 along the first axis and/or a size Lp of the piezoelectric layer 610 along the second axis can be reduced. In an example, an area of the piezoelectric layer 610 is less than an area of the substrate. In an example, an area of the piezoelectric layer 610 is less than an area of the Bragg stack 640.

A pitch p can be a center-to-center spacing along the second axis between adjacent fingers of the plurality of interleaved fingers. In an aspect, the size AP of the piezoelectric layer 610 along the first axis can be in a range from (O – T1×p) to (O + T2×p). Each of T1 and T2 can be 0 or positive values. T1 can be different from T2. In an example, T1 and T2 are less than 1. In an example, the size AP of the piezoelectric layer 610 along the first axis is equal to or substantially equal to (O + N×p). In an example, N is a value between -T1 and T2. In an example, N is a value from -T1 to T2. In some examples, comparing the cases where N<0 and N is 0, there is essentially no change in performance when N is reduced from 0 to being negative, for example, by reducing or eliminating the overlap of the piezoelectric layer 610 and the BE gap region, the loss (e.g., the transverse radiation loss) of the SM XBAR 600 is reduced. On the other hand, when N is reduced from 0 to being less than 0 (e.g., -0.5 or -1), the resonator area is reduced without or with minimal performance gain. Accordingly, in an aspect, T1 may be kept relatively small, such as N > -1. On the other side (e.g., N > 0), the transition of N from 0 to being positive is more gradual. As N increases from 0 to 1, losses can occur. In yet a further aspect, N is even smaller and between -1/4 and 1/4, which further reduces the loss (e.g., the transverse radiation loss) as described above.

In an example, |N|<1. In an example, the p pitch is equal to or is approximately equal to 2 microns, and |AP-O| (or |N×p|) is less than 0.5 microns, for example, to account for manufacturing tolerances. In this case, |N×p| < 0.25.

In an aspect, the size Lp of the piezoelectric layer 610 along the second axis can be in a range from (L – T3×p) to (L + T4×p). Each of T3 and T4 can be 0 or a positive value. T3 can be different from T4. In an example, the size Lp is equal to or substantially equal to (L + M×p). In an example, M is a value between -T3 and T4. In an example, M is 0. In an example, 0<M<1. In an example, M is a value from -T3 to T4.

An area of the piezoelectric layer 610 in a surface (e.g., an X-Y surface) parallel to the X and Y axes is Lp×AP.

In an example, the size Lp of the piezoelectric layer 610 along the second axis is L and the size AP of the piezoelectric layer 610 along the first axis is between (O –p) to (O + p). The area of the piezoelectric layer 610 is L×AP and can be comparable to the area L×O of the overlapped region 611 between the first and second plurality of fingers 636 and 637.

The area of the piezoelectric layer 610 is L×O. The first plurality of fingers 636 can extend from a first busbar 632 and the second plurality of fingers 637 can extend from a second busbar 634. When a radio frequency or a microwave signal is applied between the two busbars 632, 634, the RF voltage applied to the respective sets of IDT fingers generates a time-varying electric field that is laterally excited with respect to a surface of the piezoelectric layer 610. The SM XBAR 600 can be a variation of the SM XBAR shown in FIG. 3. In an example, the SM XBAR 600 is similar to the SM XBAR shown in FIG. 3 except that the size AP of the piezoelectric layer 610 along the first axis (e.g., the Y axis) can be limited to within the range from (O – T1×p) to (O + T2×p) and/or the size Lp of the piezoelectric layer 610 along the second axis (e.g., the X axis) can be limited to within the range from (L – T3×p) to (L + T4×p). For purposes of this disclosure, the Bragg stack 640 in the SM XBAR 600 can be similar or identical to the Bragg stack 240 in the SM XBAR shown in FIG. 3, and thus descriptions for the Bragg stack 240 in FIG. 3 can be applied to or suitably adapted for the Bragg stack 640 in the SM XBAR 600. Components labeled as 6xx in the SM XBAR 600 where xx is from 30 to 37 can be similar or identical to components labeled as 1xx in the XBAR 100, and thus descriptions for the components labeled as 1xx in the XBAR 100 can be applied to or suitably adapted for components labeled as 6xx in the SM XBAR 600. The piezoelectric layer 610 in FIGS. 6A-6B can be similar to the piezoelectric layer 110 in FIGS. 1-3 except the size AP and/or the size Lp of the piezoelectric layer 610 is limited as described in the disclosure.

According to an aspect of the disclosure, at least one trench can extend into a portion (e.g., including a layer of the Bragg stack 640) of the Bragg stack 640 in the Z axis (e.g., a thickness direction measured substantially perpendicular to the surface of the piezoelectric layer 610). The at least one trench can include a first trench extending in the second axis. The first trench can be located between the BE gaps (e.g., in a plan view of a surface of the piezoelectric layer) that are between the tips of the IDT interleaved fingers and the respective busbars, such as between the first busbar 632 and the tips of the fingers 637. In an example, the BE gaps include the area near or at the IDT-busbar region in a plan view thereof. In an example, the BE gaps include the area near or at the piezoelectric layer-busbar region in a plan view thereof. In an example, the first trench can be located between the first busbar 632 and a first edge of the piezoelectric layer 610 that is substantially parallel to the second axis and in a plan view thereof. According to an exemplary aspect, the trenches (e.g., etched regions) as described herein can be provided to improve the Q factor of the acoustic resonator by reducing acoustic leakage, and thereby improving overall filter performance of any such filters, for example, as shown in FIGS. 5A and 5B that include such acoustic resonators.

FIGS. 7A-7D show the SM XBAR 600 including the at least one trench. FIG. 7A illustrates a planar (i.e., top-down) view of the SM XBAR 6006 having the at least one trench that includes the first trench 650. In an exemplary aspect, the SM XBARs described herein with respect to FIGS. 7A-9B may have a structure similar to the SM XBAR discussed above with respect to FIGS. 3 and 6A-6B. In an example, one or more additional dielectric layers (not shown) may also be disposed between the Bragg stack 640 and the piezoelectric layer 610. In an example, one or more additional dielectric layers (not shown) may be disposed between the conductor pattern (e.g., the IDT 630, the first and second busbars 632 and 634) and the piezoelectric layer 610.

FIG. 7A shows that the interleaved fingers 636 and 637 of the IDT are connected to the first busbar 632 and the second busbar 634, respectively. The first and second busbars 632 and 634 are generally considered to be extending in the X-axis in an exemplary aspect. The first plurality of fingers 636 extends in the Y-axis (e.g., substantially perpendicularly to the X-axis) from the first busbar 632 and the second plurality of fingers 637 extends in the Y-axis from the second busbar 634.

The piezoelectric layer 610 is disposed beneath the conductor pattern that forms the interleaved fingers 636 and 637.

The at least one trench can include the first trench 650 extending in the second axis. The first trench 650 can be located between the first busbar 632 and a first edge 671 of the piezoelectric layer 610 that is substantially parallel to the second axis (the X axis). The first trench 650 can be separated from the first edge 671 of the piezoelectric layer 610 by a separation d₁ along the Y axis. The first trench 650 can be separated from tips of the second plurality of fingers 637 by a separation d₂ along the Y axis. The first trench 650 can be separated from an edge 673 of the first busbar 632 by a separation d₃along the Y axis. The first trench 650 can have a width d₄along the Y axis. The separation d₃ and the width d₄ can be of any suitable values. In an example, the separation d₃ is 0 or is approximately or substantially 0, and the first trench 650 is directly adjacent to the first busbar 632 in a planar view of the piezoelectric layer 610.

In an aspect, the separation (e.g., d₂) between the ends of the fingertips of the IDT fingers to the beginning of a trench (i.e., a first edge of the trench) is less than the spacing (e.g., d₃) between the trench (i.e., a second edge of the trench) and the opposing busbar. This configuration may be provided to reduce loss of the acoustic resonator during operation.

Each of the separations d₁, d₂, and d₃can be positive, negative, or 0. In some examples, a relatively short cantilever may be acceptable. On the other hand, in some examples, overhanging structures, such as shown in FIG. 7B, where the second plurality of fingers 637 is partially unsupported are to be avoided.

In an example, the separation d₁ is 0 or is approximately or substantially 0, and the first trench 650 is directly adjacent to the first edge 671 of the piezoelectric layer 610. In an aspect, the separation d₁ can vary from -t1 to t1, and t1 is a first threshold such as 1p, 2p, or the like. In an example, t1 is 1p. When the separation d₁ is larger than 0, there is no overlap between the first trench 650 and the piezoelectric layer 610 in the planar view of the SM XBAR, such as shown in FIG. 7A. When the separation d₁ is less than 0, there is an overlap between the first trench 650 and the piezoelectric layer 610 in the planar view of the SM XBAR (not shown in FIG. 7A).

In an example, the separation d₂ is 0 or is approximately or substantially 0, and the first trench 650 is directly adjacent to the tips of the second plurality of fingers 637. In an aspect, the separation d₂ can vary from -t2 to t2, and t2 is a second threshold such as 1p, 2p, or the like. In an example, t2 is 1p. When the separation d₂ is larger than 0, there is no overlap between the first trench 650 and the second plurality of fingers 637 in the planar view of the SM XBAR, such as shown in FIG. 7A. When the separation d₂ is less than 0, there is an overlap between the first trench 650 and the second plurality of fingers 637 in the planar view of the SM XBAR (not shown in FIG. 7A).

In an example, O and AP are equal, and the tips of the second plurality of fingers 637 end at the first edge 671 of the piezoelectric layer 610, and d₁ is equal to d₂.

In an aspect, the at least one trench can include a second trench 651 extending in the second axis. The second trench 651 can be located between the second busbar 634 and a second edge 672 of the piezoelectric layer 610 that is substantially parallel to the second axis. The second trench 651 can be separated from the second edge 672 of the piezoelectric layer 610 by a separation d₅ along the Y axis. The second trench 651 can be separated from tips of the first plurality of fingers 636 by a separation d₆ along the Y axis. The second trench 651 can be separated from an edge 674 of the second busbar 634 by a separation d₇ along the Y axis. The second trench 651 can have a width d₈ along the Y axis. The separation d₇ and the width d₈ can be any suitable values.

The discussion of d₁ can be applied to d₅. d₁ can be equal to or different from d₅. The discussion of d₂can be applied to d₆. d₂ can be equal to or different from d₆. The discussion of d₃ can be applied to d₇. d₃ can be equal to or different from d₇. The discussion of d₄can be applied to d₈. d₄ can be equal to or different from d₈. In an example, the separation d₇ is 0 or is approximately or substantially 0, and the second trench 651 is directly adjacent to the second busbar 634 in the planar view of the piezoelectric layer 610. Each of the separations d₅, d₆ and d₇ can be positive, negative, or 0. In an example, the separation d₅ is 0 or is approximately or substantially 0, and the second trench 651 is directly adjacent to the second edge 672 of the piezoelectric layer 610. In an aspect, the separation d₅ can vary from -t5 to t5, and t5 is a threshold such as 1p, 2p, or the like. In an example, t5 is 1p. When the separation d₅ is larger than 0, there is no overlap between the second trench 651 and the piezoelectric layer 610 in the planar view of the SM XBAR, such as shown in FIG. 7A. When the separation d₅ is less than 0, there is an overlap between the second trench 651 and the piezoelectric layer 610 in the planar view of the SM XBAR (not shown in FIG. 7A).

In an example, the separation d₆is 0 or is approximately or substantially 0, and the second trench 651 is directly adjacent to the tips of the first plurality of fingers 636. In an aspect, the separation d₆ can vary from -t6 to t6, and t6 is a threshold such as 1p, 2p, or the like. In an example, t6 is 1p. When the separation d₆ is larger than 0, there is no overlap between the second trench 651 and the first plurality of fingers 636 in the planar view of the SM XBAR, such as shown in FIG. 7A. When the separation d₆is less than 0, there is an overlap between the second trench 651 and the first plurality of fingers 636 in the planar view of the SM XBAR (not shown in FIG. 7A).

In an example, O and AP are equal, and the tips of the first plurality of fingers 636 end at the second edge 672 of the piezoelectric layer 610, and d₅ is equal to d₆.

In an example, d₁ is less than d₃. In an example, d₅ is less than d₇.

The at least one trench can have any suitable shape and can include any suitable number of one or more trenches. In the example of FIG. 7A, the at least one trench includes two trenches, the first trench 650 and the second trench 651. In other examples, the at least one trench includes more than two trenches or less than two trenches. In the example of FIG. 7A, the first trench 650 and the second trench 651 have a rectangular shape in the planar view of the piezoelectric layer 610. The first trench 650 and/or the second trench 651 can have other shapes. The first trench 650 and/or the second trench 651 can extend a length that is comparable to Lp or L along the X-axis, as shown in FIG. 7A. Alternatively, the first trench 650 and/or the second trench 651 can extend a length that is less than or larger than Lp along the X-axis.

FIG. 8 shows an example of trenches where each trench extends a length that is shorter (e.g., significantly shorter) than Lp or L along the X-axis. Each trench 850 in the top row is located between a different set of adjacent fingers 636 extending from the top busbar 632, in a horizontal or lengthwise direction (e.g., the second direction). Each trench 851 in the bottom row of FIG. 8 is located between a different set of adjacent fingers 637 extending from the bottom busbar 634, in a horizontal or lengthwise direction (e.g., the second direction). While the exemplary aspect of FIG. 8 shows a trench 850 or 851 between each set of adjacent fingers, the number of trenches is not limited to the exemplary configuration of FIG. 8. More or fewer trenches may be included in the SM XBAR in other aspects.

In FIG. 8, each trench 850 and the location of the trench 850 along the Y axis can be similar or identical to the first trench 650 except that the length of the trench 850 along the X-axis is less than that of the first trench 650. Each trench 851 and the location of the trench 851 along the Y axis can be similar or identical to the second trench 651 except that the length of the trench 851 along the X-axis is less than that of the second trench 651.

In some examples, the trenches are between the edge of the piezoelectric layer and an edge of the opposing busbar, such as shown in FIGS. 7B-7D. In some examples, the trenches are beneath the fingers that extend from the same busbar in the BE gap between the busbar and the opposing fingers, such as shown in FIGS. 7C and 7D.

FIGS. 7B-7D show cross-sectional views of the areas denoted with dashed lines (i.e., Section A-A and Section B-B) in FIG. 7A, which pass through the first trench 650 and the second trench 651, respectively. While the substrate is not shown in the cross-sectional views of FIGS. 7B-7D, the substrate is understood to support (or partially support) the Bragg stack 640, as shown in FIG. 3. Furthermore, the full Bragg stack 640 may not be shown in FIGS. 7B-7D, which shows only the four alternating layers 640a, 640b, 640c, and 640d. The Bragg stack 640 may include more or fewer layers (e.g., layers 640a to 640d) in alternative aspects.

FIG. 7B shows a cross-sectional view of the area denoted with a dashed line (i.e., Section A-A) in FIG. 7A, which passes through the first trench 650. The first trench 650 shown in FIG. 7B shows partial removal (e.g., one or more layers 640a and 640b) of the Bragg stack 640, such that a thickness of the Bragg stack 640 is smaller in the first trench 650 than a thickness of another region of the Bragg stack 640 that is outside of the first trench 650. As further shown, the first trench 650 is positioned in an area where there is no busbar. The first busbar 632 is to the right of the first trench 650 in FIG. 7B. Moreover, the tip of one of fingers 637 is shown to the left of the first trench 650. As further shown in this exemplary aspect, the trench 650 is offset from at least one of edge of the piezoelectric layer 610 and an edge of the busbar 632 of the IDT in a plan view of the piezoelectric layer 610, which can provide additional mechanical stability during the manufacturing process, for example.

FIG. 7C shows a cross-sectional view of the area denoted with the dashed line (i.e., Section B-B) in FIG. 7A, which passes through the second trench 651. The second trench 651 shown in FIG. 7C shows partial removal (e.g., one or more layers 640a and 640b) of the Bragg stack 640, such that a thickness of the Bragg stack 640 is smaller in the second trench 651 than a thickness of another region of the Bragg stack 640 that is outside of the second trench 651. This configuration of a partial trench can provide improved mechanical stability of the acoustic resonator 600 according to an exemplary aspect. Moreover, as further shown, the second trench 651 is positioned in an area where there is no busbar, for example, the second busbar 634 is to the left of the second trench 651 in FIG. 7C. In this case, the tip of one of fingers 637 is over the second trench 651. The trench 651 is beneath the fingers 637 that extend from the same busbar 634 in the BE gap between the busbar 634 and the opposing fingers 636.

FIG. 7D shows cross-sectional view illustrating the trench of FIG. 7A according to another exemplary aspect. In particular FIG. 7D illustrates a similar configuration as FIG. 7C, except that the trench 650D has a wider width d₅ than width d₄ as shown in FIG. 7C and discussed above. In this aspect, the trench 650D extends to the edge (e.g., side of the piezoelectric layer 610) in the plan view thereof (i.e., the Z-axis direction). According to this configuration, the trench 650D is configured as an air gap adjacent to and substantially aligned with the piezoelectric layer 610 in the plan view to further improve acoustic confinement of the waves propagating through the piezoelectric layer 610 during excitation of the acoustic resonators IDTs in operation. It should be appreciated that when the trench 650D is substantially aligned to the piezoelectric layer 610, this means that the alignment may vary slightly taking into account minor manufacturing variances.

In general, according to an exemplary aspect, the metal busbars 632 and/or 634 can be mounted directly onto the Bragg stack 640 or can be disposed on a dielectric layer that is over the Bragg stack 640. Referring to FIGS. 7B-7D, the metal busbars 632 and 634 are disposed on a dielectric layer (or an appropriate filler such as another metal layer that is different or the same as the material in the metal busbars 632 and 634) 732 and 734, respectively. In an example, the dielectric layers 732 and 734 include an oxide layer that is acoustically isolated.

In an example, the at least one trench such as the first trench 650 extends fully through the Bragg stack 640. In an example, the at least one trench such as the first trench 650 extends partially through the substrate.

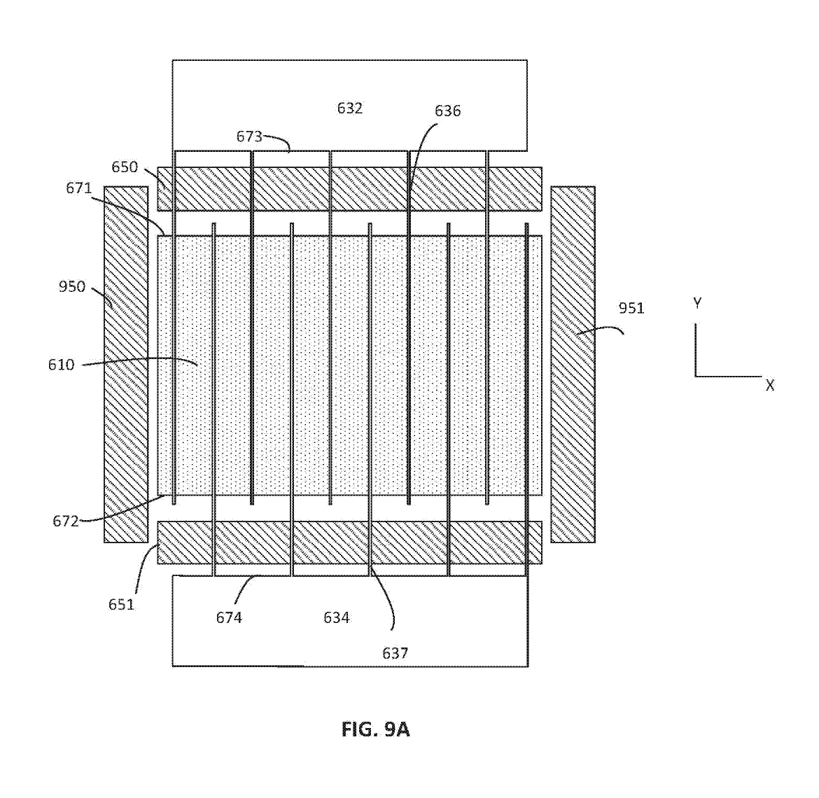

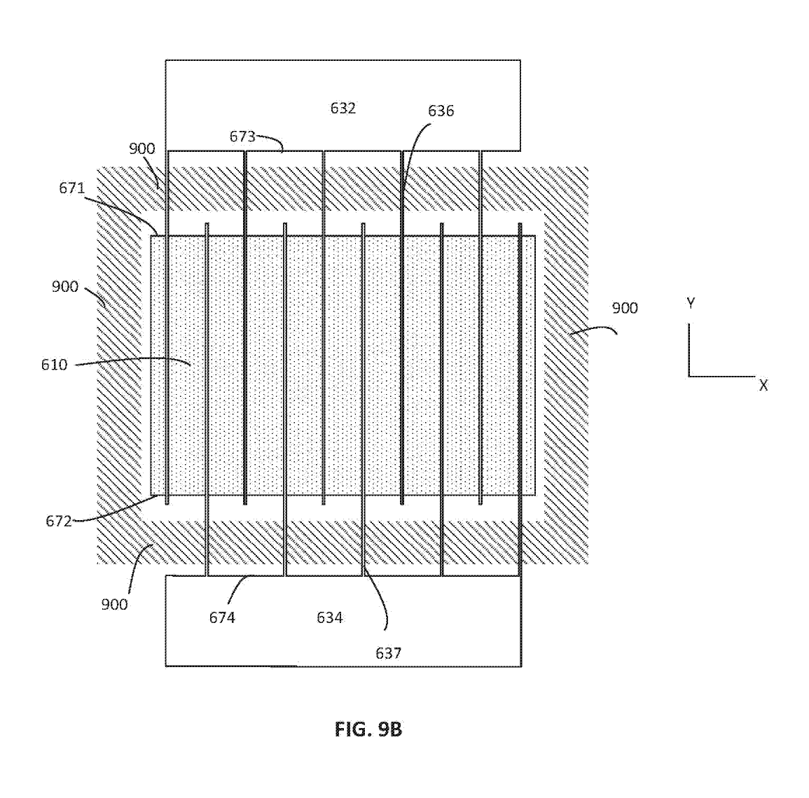

In some examples, the at least one trench includes one or more trenches that extend along the Y-axis, such as shown in FIGS. 9A-9B. FIG. 9A shows an example where the at least one trench includes the trenches 650 and 651 described in FIGS. 7A-7C and trenches 950 and 951 that extend along the Y axis. In the trench 950-951, one or more layers such as 640a and 640b are removed from the Bragg stack 640, such that a thickness of the Bragg stack 640 is smaller in the trenches 950-951 than a thickness of another region of the Bragg stack 640 that is outside of the trenches 950-951. In an example, an edge of one of the trenches 650-651 and 950-951 coincides with an edge of the piezoelectric layer 610. In an example, each edge of the trenches 650-651 and 950-951 coincides with a respective edge of the piezoelectric layer 610.

In another example, at least two of the trenches 650-651 and 950-951 can be connected. In another example shown in FIG. 9B, the trenches 650-651 and 950-951 are connected and are merged into a trench 900 (e.g., an etched region). For example, the two trenches 650-651 are connected to each other at the edges of the IDT via the trenches 950-951, as shown in FIG. 9B.

According to this exemplary aspect, connecting trenches may be formed on either side of the interleaved fingers of the IDT to effectively form a continuous (e.g., rectangular shaped) trench 900. In FIG. 9B, the connecting trenches run vertically, parallel with the extension direction of the IDT fingers, and connect the ends of the two trenches (e.g., the top and bottom trenches in FIGS. 7A) to each other. As a result, the plurality of interleaved fingers of the IDT (e.g., fingers 636 and 637) are disposed between the two connecting trenches of the trench 900 in a planar view of the piezoelectric layer 610.

Although trench 900 is shown as a rectangular in an exemplary aspect, the shape of this continuous trench is not so limited and can be an oval or a rectangle with curved corners in alternative aspects.

According to the exemplary aspects shown in FIGS. 7A-7D, the trenches 650, 650D, 651 of the exemplary aspect achieves an improved Q factor by reducing acoustic leakage in the BE gap while also provided no mechanical issues since the piezoelectric layer 610 is otherwise solidly mounted to the Bragg stack 640 (including layers 640a to 640d). Additionally, in some examples, fabrication of the trenches 650 and 651 is achieved without etching through the busbars 632 and 634. Moreover, the etching process does not require precise timing control and constraints. As a result, the depth of the first trench 650 may be different in exemplary aspects. In yet other exemplary aspects, the Bragg stack may be fully removed in the trench, with or without partial removal of the underlying substrate. As described herein with respect to FIGS. 7B-7D, the depth of the trench is measured vertically (i.e., in the Z axis direction) in these figures, in a direction perpendicular to the planar dimension of the piezoelectric layer 610.

The exemplary aspects of FIGS. 6A, 6B, 7A-7D, 8, and 9A-9B, may be combined in any one of various suitable ways, with respect to location, shape, and number of trenches. The specific trench configuration that can optimize Q for a particular SM XBAR structure and the specific dimensions of the piezoelectric layer 610 may be based on the material and cut of the piezoelectric material (e.g., 120Y lithium niobate, 120Y lithium tantalate, 82Y, etc.), among other factors.

Thus, as generally described herein, for existing solidly-mounted XBAR designs, the piezoelectric layer extends well beyond the active aperture area of the interdigital transducer, including underneath and past the busbars. This extended piezoelectric layer provides a path for acoustic energy to propagate laterally away from the active region of the resonator, causing leakage or loss during operation. This acoustic energy radiating outward from the edges of the active region can account for a significant portion of the overall loss budget. By reducing the footprint of the piezoelectric layer so that it is substantially limited to the overlap area defined by the interleaved IDT fingers, the lateral propagation path for this transverse radiation is curtailed. The various loss mechanisms in the resonator are understood to be substantially independent of one another, which means that reducing the transverse three-dimensional radiation loss through this structural modification can yield a net reduction in overall device loss without adversely increasing other loss components.

Additionally, because the resonator is solidly mounted on a Bragg stack rather than suspended above a cavity, the reduced-area piezoelectric layer remains mechanically robust and does not suffer from potential fragility concerns associated with suspended membrane architectures. As described herein, the performance benefits can be further enhanced by forming trenches in one or more layers of the Bragg stack at the periphery of the piezoelectric layer. These trenches create an air barrier that inhibits acoustic energy from radiating laterally through the Bragg stack layers that would otherwise remain present beyond the edge of the piezoelectric layer. The primary trench, positioned proximate to the tips of the opposing IDT fingers, can be an effective confinement mechanism because a substantial portion of the transverse radiation originates in the region between the fingertips and the busbars. Moreover, a secondary trench extending along the outermost fingers in the overlap direction may provide additional benefit.

Finally, it is noted that as used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator comprising:
a piezoelectric layer;
a Bragg stack disposed between a substrate of the acoustic resonator and the piezoelectric layer; and
an interdigital transducer (IDT) at a surface of the piezoelectric layer that faces away from the Bragg stack, the IDT including a plurality of fingers including a first plurality of fingers and a second plurality of fingers that are interleaved and extend in a direction substantially along a first axis, the first and second plurality of fingers overlapping for a distance O along the first axis,
wherein a center-to-center distance L along a second axis substantially perpendicular to the first axis is between outermost fingers of the plurality of fingers of the IDT, and
wherein a pitch p is a center-to-center spacing along the second axis between adjacent fingers of the plurality of fingers, a size AP of the piezoelectric layer along the first axis is substantially equal to (O + N×p), N is a value between -1 and 1, and a size Lp of the piezoelectric layer along the second axis is substantially equal to (L + M×p), and M is a value between 0 and 1.

2. The acoustic resonator of claim 1, wherein N is between -1/4 and 1/4.

3. The acoustic resonator of claim 1, wherein the first plurality of fingers extends from a first busbar and the second plurality of fingers extends from a second busbar, at least one trench extends into at least one layer of the Bragg stack that includes a plurality of layers in a thickness direction measured substantially perpendicular to a surface of the piezoelectric layer, and the at least one trench includes a first trench extending in the second axis, the first trench being located between the first busbar and a first edge of the piezoelectric layer that is substantially parallel to the second axis.

4. The acoustic resonator of claim 3, wherein the first trench is offset from at least one of the first edge of the piezoelectric layer and an edge of the first busbar in a plan view of the piezoelectric layer.

5. The acoustic resonator of claim 4, wherein the first trench is directly adjacent to the first busbar in a planar view of the piezoelectric layer.

6. The acoustic resonator of claim 3, wherein the Bragg stack is partially removed in the at least one trench, such that a thickness of the Bragg stack is smaller in the at least one trench than a thickness of the Bragg stack outside of the at least one trench.

7. The acoustic resonator of claim 3, wherein the at least one trench includes a second trench extending in the second axis, the second trench being located between the second busbar and a second edge of the piezoelectric layer that is substantially parallel to the second axis.

8. The acoustic resonator of claim 7, wherein the second trench is directly adjacent to the second edge of the piezoelectric layer.

9. The acoustic resonator of claim 7, wherein the first trench and the second trench are connected to each other by two connecting trenches extending along the first axis, such that the piezoelectric layer is disposed between the two connecting trenches in a planar view of the piezoelectric layer.

10. The acoustic resonator of claim 3, wherein the at least one trench extends fully through the Bragg stack.

11. The acoustic resonator of claim 3, wherein the first busbar and the second busbar are directly mounted on the Bragg stack or are directly mounted on a dielectric layer that is over the Bragg stack.

12. A filter device comprising:
a plurality of bulk acoustic resonators, each including:
a piezoelectric layer;
a Bragg stack disposed between a substrate and the piezoelectric layer; and
an interdigital transducer (IDT) at a surface of the piezoelectric layer that faces away from the Bragg stack, the IDT including a plurality of fingers including a first plurality of fingers and a second plurality of fingers that are interleaved and that extend in a direction substantially along a first axis, the piezoelectric layer disposed between the IDT and the Bragg stack, the first and second plurality of fingers overlapping for a distance O along the first axis,
wherein a center-to-center distance L along a second axis substantially perpendicular to the first axis is between outermost fingers of the plurality of fingers of the IDT, and
wherein a pitch p is a center-to-center spacing along the second axis between adjacent fingers of the plurality of fingers, a size AP of the piezoelectric layer along the first axis is substantially equal to (O + N×p), N is a value between -1 and 1, and a size Lp of the piezoelectric layer along the second axis is substantially equal to (L + M×p), and M is a value between 0 and 1.

13. The filter device of claim 12, wherein N is between -1/4 and 1/4.

14. The filter device of claim 12, wherein the first plurality of fingers extends from a first busbar and the second plurality of fingers extends from a second busbar, at least one trench extends into at least one layer of the Bragg stack that includes a plurality of layers in a thickness direction measured substantially perpendicular to a surface of the piezoelectric layer, and the at least one trench includes a first trench extending in the second axis, the first trench being located between the first busbar and a first edge of the piezoelectric layer that is substantially parallel to the second axis.

15. The filter device of claim 14, wherein the first trench is directly adjacent to the first edge of the piezoelectric layer.

16. The filter device of claim 14, wherein the first trench is offset from at least one of the first edge of the piezoelectric layer and an edge of the first busbar in a plan view of the piezoelectric layer.

17. The filter device of claim 14, wherein the Bragg stack is partially removed in the at least one trench, such that a thickness of the Bragg stack is smaller in the at least one trench than a thickness of the Bragg stack outside of the at least one trench.

18. The filter device of claim 14, wherein the at least one trench includes a second trench extending in the second axis, the second trench being located between the second busbar and a second edge of the piezoelectric layer that is substantially parallel to the second axis.

19. The filter device of claim 18, wherein the second trench is directly adjacent to the second edge of the piezoelectric layer.

20. A radio frequency module, comprising:
a filter device including a plurality of bulk acoustic resonators; and
a radio frequency circuit coupled to the filter device, the filter device and the radio frequency circuit being enclosed within a common package,
wherein at least one acoustic resonator of the plurality of bulk acoustic resonators of the filter device includes:
a piezoelectric layer;
a Bragg stack disposed between a substrate and the piezoelectric layer; and
an interdigital transducer (IDT) at a surface of the piezoelectric layer that faces away from the Bragg stack, the IDT including a plurality of fingers including a first plurality of fingers and a second plurality of fingers that are interleaved and are substantially parallel along a first axis, the piezoelectric layer disposed between the IDT and the Bragg stack, the first and second plurality of fingers overlapping for a distance O along the first axis,
wherein a center-to-center distance L along a second axis substantially perpendicular to the first axis is between outermost fingers of the plurality of fingers of the IDT, and
wherein a pitch p is a center-to-center spacing along the second axis between adjacent fingers of the plurality of fingers, a size AP of the piezoelectric layer along the first axis is substantially equal to (O + N×p), N is a value between -1 and 1, and a size Lp of the piezoelectric layer along the second axis is substantially equal to (L + M×p), and M is a value between 0 and 1.
